(19) United States
(12) Patent Application Publication
(10) Pub. No.: US 2007/0236262 A1
(43) Pub. Date: Oct. 11, 2007

(54) LOW VOLTAGE OUTPUT CIRCUIT

(75) Inventor: David McClure, Carrollton, TX (US)

Correspondence Address: STMICROELECTRONICS, INC., MAIL STATION 2346, 1310 ELECTRONICS DRIVE, CARROLLTON, TX, 75006, US

(73) Assignee: STMICROELECTRONICS, INC., Carrollton, TX (US)

(21) Appl. No.: 11/733,072

(22) Filed: Apr. 9, 2007

Related U.S. Application Data
(60) Provisional application No. 60/744,569, filed on Apr. 10, 2006.

(51) Int. Cl. H03B 1/00

(52) U.S. Cl. 327/108

(57) ABSTRACT

An output driver for an integrated circuit that asserts at very low power supply voltages includes a first input voltage node, a first power supply voltage node, an output voltage node, a first internal circuit node, a first resistive element coupled between the first power supply voltage node and the first internal node, a first transistor having a gate coupled to first input voltage node, a drain coupled to the first power supply voltage node, and a source coupled to ground, a second transistor having a gate coupled to the first internal circuit node, a drain coupled to the output voltage node, and a source coupled to ground, and a third transistor having a gate coupled to the first internal circuit node, a drain coupled to the output voltage node, and a source coupled to ground, wherein the first and second transistors have a first Vt threshold voltage, and the third transistor has a second Vt threshold voltage lower than the first threshold voltage. Two or more such circuits driver circuits can be used in conjunction to monitor two or more power supply voltages.

### RELATED APPLICATION

The present application claims priority from U.S. Provisional Application No. 60/744,569, filed Apr. 10, 2006. The disclosure of the foregoing United States Patent Application is specifically incorporated herein by this reference in its entirety.

### BACKGROUND OF THE INVENTION

The present invention is an output driver for an integrated circuit that asserts at very low power supply voltages, such as voltages down to 0.4 volts.

The output driver of the present invention can ideally be used in “supervisor” circuits, which are known. Supervisors circuits are used to monitor low voltages or low supply currents associated with processor circuits, for example, and can typically monitor two or three system power supply voltages at the same time. The supervisor circuits can typically monitor the power supply voltages using different threshold voltages, some of which may be adjustable by the end user. If any of the monitored voltages drop below the threshold for that power supply, a reset signal is typically asserted. Once asserted, the reset signal is maintained until all of the monitored supplies rise back above the selected threshold voltage.

One problem with prior art driver circuits is that the use of low-voltage threshold driving circuits can lead to excessive leakage currents that may be in excess of desired leakage current specifications. What is desired, therefore, is an output driver suitable for use in very low voltage conditions, but with less leakage current than that of prior art solutions.

### SUMMARY OF THE INVENTION

An output driver for an integrated circuit that asserts at very low power supply voltages includes a first input voltage node, a first power supply voltage node, an output voltage node, a first internal circuit node, a first resistive element coupled between the first power supply voltage node and the first internal node, a first transistor having a gate coupled to first input voltage node, a drain coupled to the first power supply voltage node, and a source coupled to ground, a second transistor having a gate coupled to the first internal circuit node, a drain coupled to the output voltage node, and a source coupled to ground, and a third transistor having a gate coupled to the first internal circuit node, a drain coupled to the output voltage node, and a source coupled to ground, wherein the first and second transistors have a first Vt threshold voltage, and the third transistor has a second Vt threshold voltage lower than the first threshold voltage.

Two or more such circuits driver circuits can be used in conjunction to monitor two or more power supply voltages.

### BRIEF DESCRIPTION OF THE DRAWINGS

The aforementioned and other features and objects of the present invention and the manner of attaining them will become more apparent and the invention itself will be best understood by reference to the following description of a preferred embodiment taken in conjunction with the accompanying drawings, wherein:

FIG. 1 shows a driver circuit according to an embodiment of the invention; and

FIG. 2 shows that a P-channel transistor can be substituted for a pullup resistor used in the circuit of FIG. 1.

### DETAILED DESCRIPTION OF THE INVENTION

A first half of circuit 10 includes an input voltage node VIN1, a power supply voltage node VCC1, an output voltage node VOUT, and an internal circuit node 12. The VCC1 voltage can range between 3.0 and 5.5 volts under normal operating conditions. However, in low voltage conditions, the VCC1 power supply voltage can go as low as 0.4 volts. The VIN1 voltage swings between ground and VCC1. The first half of circuit 10 includes transistors Q1, Q2, and Q3. Transistors Q1 and Q2 have a “normal” Vt threshold voltage of about 0.7 volts. Transistor Q3 has a “low” Vt threshold voltage of about 0.4 volts. A resistor R1 is coupled between the VCC1 power supply voltage node and node 12, which is the drain of transistor Q1. The gate of transistor Q1 receives the VIN1 input voltage. Node 12 is coupled to the gates of both transistors Q2 and Q3. The sources of transistors Q1, Q2, and Q3 are all coupled to ground. The drains of transistors Q2 and Q3 are coupled together and form the VOUT output voltage, which drives an external integrated circuit PAD.

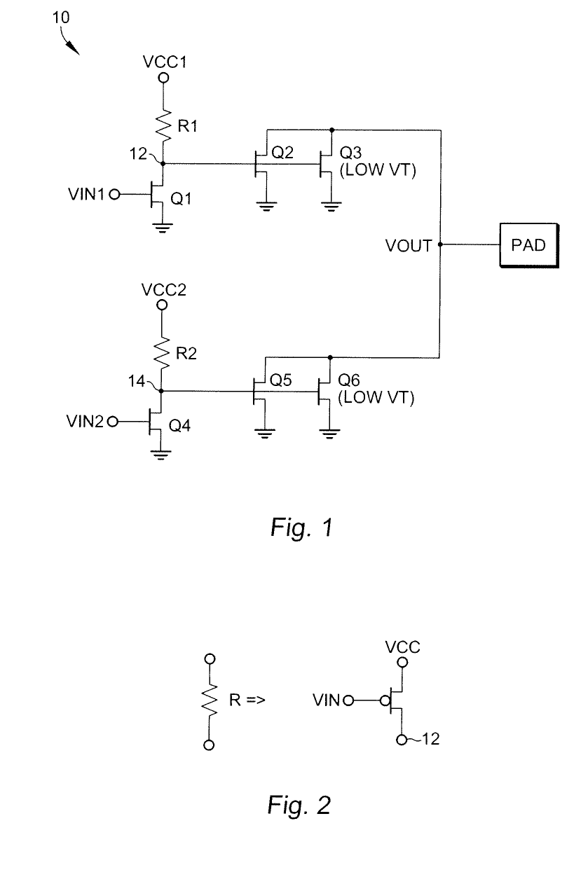

One use for the first half of circuit 10 is to monitor the voltage of the VCC1 pin itself through logic and other circuitry not shown in FIG. 1. During normal conditions when the VCC1 power supply voltage is above a predetermined threshold voltage, VIN1 is equal to VCC1. Node 12 is brought low, which turns off transistors Q2 and Q3. Thus, the VOUT voltage is high and achieves a voltage level determined by the pullup load coupled to the PAD. During a low voltage condition when the VCC1 power supply voltage is below the predetermined threshold voltage, VIN1 is at ground voltage. Node 12 is brought close to VCC1, and transistors Q2 and Q3 are turned on. Thus, the VOUT voltage is low, which is an indication to the circuitry coupled to the PAD that VCC1 is in a low voltage condition.

More than one power supply can be monitored by the circuit of the present invention. If a second power supply voltage VCC2 is desired to be monitored, a second “half” of the circuit 10 can be used as is described below.

A second half of circuit 10 includes an input voltage node VIN2, a power supply voltage node VCC2, a shared output voltage node VOUT, and an internal circuit node 14. The VCC2 voltage can range between 3.0 and 5.5 volts under normal operating conditions. However, in low voltage conditions, the VCC2 power supply voltage can go as low as 0.4 volts. The VIN2 voltage swings between ground and VCC2. The second half of circuit 10 includes transistors Q4, Q5, and Q6. Transistors Q4 and Q5 have a “normal” Vt threshold voltage of about 0.7 volts. Transistor Q6 has a “low” Vt threshold voltage of about 0.4 volts. A resistor R2 is coupled between the VCC2 power supply voltage node and node 14, which is the drain of transistor Q4. The gate of transistor Q4 receives the VIN2 input voltage. Node 14 is coupled to the gates of both transistors Q5 and Q6. The sources of transistors Q4, Q5, and Q6 are all coupled to ground. The drains of transistors Q5 and Q6 are coupled together and form the VOUT output voltage, which drives an external integrated circuit PAD.

One use for the second half of circuit 10 is to monitor the voltage of the VCC2 pin itself through logic and other circuitry not shown in FIG. 1. During normal conditions when the VCC2 power supply voltage is above a predetermined threshold voltage, VIN2 is equal to VCC1. Node 14 is brought low, which turns off transistors Q5 and Q6. Thus, the VOUT voltage is high and achieves a voltage level determined by the pullup load coupled to the PAD. During a low voltage condition when the VCC2 power supply voltage is below the predetermined threshold voltage, VIN is at ground voltage. Node 14 is brought close to VCC2, and transistors Q5 and Q6 are turned on. Thus, the VOUT voltage is low, which is an indication to the circuitry coupled to the PAD that VCC2 is in a low voltage condition.

The present invention can be extended to monitor multiple power supply voltages, wherein each of the circuit portions would be joined together at the common VOUT voltage to drive the PAD, in a wired OR arrangement. This allows for asserting PAD low when Vthreshold1>VCC1>0.4V AND/OR Vthreshold2>VCC2>0.4V.

In a typical application, resistors R1 and R2 are between three and five megohms. Transistors Q1 and Q4 have a size of about 10 by 0.8 microns. Transistors Q2 and Q5 have a size of about 150 by 1.0 microns. Transistors Q3 and Q6 have a size of about 50 by 2 microns.

In an embodiment of the invention, a pullup resistor (R1 or R2) is used instead of or in addition to a P-channel pullup transistor. P-channel transistors typically have a large Vt threshold voltage and thus are not optimum for low voltage applications in which the threshold voltage actually exceeds the total power supply voltage available. Using a resistor as the pullup removes the limitation of the P-channel Vt.

However, a P-channel transistor can actually be used as shown in FIG. 2, and the current drain through the pullup resistor eliminated if one condition is met. The P-channel pullup transistor shown in FIG. 2. can be used if the P-channel active diffusion coupled to node 12 is made significantly larger than the corresponding active N-diffusion of transistor Q1. Sizing the active diffusions in this manner will allow a net leakage current to VCC1, and will allow the use of the P-channel pullup resistor even if the Vt threshold voltage exceeds the power supply voltage.

The N-driver itself (Q2 and Q3 or Q5 and Q6) is composed of low Vt device and a normal Vt device. The reason for using both types of transistors is that the low Vt device having a threshold voltage Vt of 0.4 V may be leaky at high temperatures. To meet leakage specifications, it may be required that only part of the output driver be a low Vt device. To meet total current driving specifications during normal operation, the other device should be a normal Vt transistor. An ideal combination of devices would satisfy both leakage current and drive current specifications. If however, leakage current specifications can be relaxed, it may be possible to “merge” transistors Q2 and Q3 or Q5 and Q6 into a single low Vt device.

The present invention is not limited to power supply monitoring circuitry, but can be used as an all-purpose output driver suitable for use with very low power supply voltages.

While there have been described above the principles of the present invention in conjunction with specific implementations and device processing technology, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The applicants hereby reserve the right to formulate new claims to such features and/or combinations of such features during the prosecution of the present application or of any further application derived therefrom.

We claim:

1. An output driver for an integrated circuit that asserts at very low power supply voltages comprising:
a first input voltage node;
a first power supply voltage node;
an output voltage node;
a first internal circuit node;
a first resistive element coupled between the first power supply voltage node and the first internal node;
a first transistor having a gate coupled to first input voltage node, a drain coupled to the first power supply voltage node, and a source coupled to ground;
a second transistor having a gate coupled to the first internal circuit node, a drain coupled to the output voltage node, and a source coupled to ground; and
a third transistor having a gate coupled to the first internal circuit node, a drain coupled to the output voltage node, and a source coupled to ground, wherein the first and second transistors have a first Vt threshold voltage, and the third transistor has a second Vt threshold voltage lower than the first threshold voltage.

2. The output driver of claim 1 wherein the output voltage node is coupled to an external integrated circuit pad.

3. The output driver of claim 1 wherein the first Vt threshold voltage is about 0.7 volts.

4. The output driver of claim 1 wherein the second Vt threshold voltage is about 0.4 volts.

5. The output driver of claim 1 wherein the voltage at the first power supply voltage node ranges between 3.0 and 5.5 volts under normal operating conditions.

6. The output driver of claim 1 wherein the voltage at the first power supply voltage node goes as low as 0.4 volts in a low voltage condition.

7. The output driver of claim 1 wherein, during normal conditions when the first power supply voltage at the first power supply voltage node is above a predetermined threshold voltage, the first input voltage at the first input voltage node is equal to the first power supply voltage.

8. The output driver of claim 1 wherein, during a low voltage condition when the first power supply voltage at the first power supply voltage node is below a predetermined threshold voltage, the first input voltage at the first input voltage node is at ground voltage.

9. The output driver of claim 1 wherein the first resistive element comprises a resistor having a value of between three and five megohms.

10. The output driver of claim 1 wherein the first resistive element comprises a P-channel pullup transistor.

11. The output driver of claim 1, further comprising:
a second input voltage node;
a second power supply voltage node;
a second internal circuit node;
a second resistive element coupled between the second power supply voltage node and the second internal node;
a fourth transistor having a gate coupled to second input voltage node, a drain coupled to the second power supply voltage node, and a source coupled to ground;
a fifth transistor having a gate coupled to the second internal circuit node, a drain coupled to the output voltage node, and a source coupled to ground; and
a sixth transistor having a gate coupled to the second internal circuit node, a drain coupled to the output voltage node, and a source coupled to ground,
wherein the fourth and fifth transistors have a first Vt threshold voltage, and the sixth transistor has a second Vt threshold voltage lower than the first threshold voltage.

12. The output driver of claim 11 wherein the first Vt threshold voltage is about 0.7 volts.

13. The output driver of claim 11 wherein the second Vt threshold voltage is about 0.4 volts.

14. The output driver of claim 11 wherein the voltage at the second power supply voltage node ranges between 3.0 and 5.5 volts under normal operating conditions.

15. The output driver of claim 11 wherein the voltage at the second power supply voltage node goes as low as 0.4 volts in a low voltage condition.

16. The output driver of claim 11 wherein, during normal conditions when the second power supply voltage at the second power supply voltage node is above a predetermined threshold voltage, the second input voltage at the second input voltage node is equal to the second power supply voltage.

17. The output driver of claim 11 wherein, during a low voltage condition when the second power supply voltage at the second power supply voltage node is below a predetermined threshold voltage, the second input voltage at the second input voltage node is at ground voltage.

18. The output driver of claim 11 wherein the second resistive element comprises a resistor having a value of between three and five megohms.

19. The output driver of claim 11 wherein the second resistive element comprises a P-channel pullup transistor.

20. An output driver for an integrated circuit that asserts at very low power supply voltages comprising a plurality of driver sections coupled together at an output voltage node, each driver section comprising:
an input voltage node;
a power supply voltage node;
an output voltage node;
an internal circuit node;
a resistive element coupled between the power supply voltage node and the internal node;
a first transistor having a gate coupled to input voltage node, a drain coupled to the power supply voltage node, and a source coupled to ground;
a second transistor having a gate coupled to the internal circuit node, a drain coupled to the output voltage node, and a source coupled to ground; and
a third transistor having a gate coupled to the internal circuit node, a drain coupled to the output voltage node, and a source coupled to ground,
wherein the first and second transistors have a first Vt threshold voltage, and the third transistor has a second Vt threshold voltage lower than the first threshold voltage, and wherein only the output node is shared between the plurality of driver sections.

21. An output driver for an integrated circuit that asserts at very low power supply voltages comprising a plurality of driver sections coupled together at an output voltage node, each driver section comprising:
a first driver transistor for driving an output voltage node; and
a second driver transistor for driving the output voltage node,
wherein the first and second transistors have a first Vt threshold voltage, and the third transistor has a second Vt threshold voltage lower than the first threshold voltage, and wherein the first and second driver transistors are switched together between a normal operating mode and a low voltage mode.

22. An output driver for an integrated circuit that asserts at very low power supply voltages comprising:
a first input voltage node;
a first power supply voltage node;
an output voltage node;
a first internal circuit node;
a first resistive element coupled between the first power supply voltage node and the first internal node;
a first transistor having a gate coupled to first input voltage node, a drain coupled to the first power supply voltage node, and a source coupled to ground; and
a second transistor having a gate coupled to the first internal circuit node, a drain coupled to the output voltage node, and a source coupled to ground.

23. The output driver of claim 22 wherein the first transistor has a first Vt threshold voltage, and the second transistor has a second Vt threshold voltage lower than the first threshold voltage.
